(19) United States
(12) Patent Application Publication
(10) Pub. No.: US 2025/0142788 A1
(43) Pub. Date: May 1, 2025

(54) BOX-TYPE LIQUID COOLING DEVICE FOR DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/900,824

(22) Filed: Sep. 29, 2024

(30) Foreign Application Priority Data
Nov. 1, 2023 (CN) 202311448393.8

(51) Int. Cl. H05K 7/20

(52) U.S. Cl. CPC H05K 7/20781; H05K 7/20736

(57) ABSTRACT

The present disclosure discloses a box-type liquid cooling device for a data center, including a box body. A box door is hinged on the box body, a control box is fixedly installed on the box door, and a ventilation mechanism is arranged on the box body. A mounting plate is connected to interior of the box body through a screw, a support frame is connected to the interior of the box body through the screw, and a liquid cooling tank is fixedly connected to the mounting plate. The liquid cooling tank is connected to the support frame through the screw, and a heat exchange box is fixedly connected to the support frame.

### CROSSREFERENCE TO RELATED APPLICATION

This application claims priority to Chinese Patent Application No. 202311448393.8, titled “BOX-TYPE LIQUID COOLING DEVICE FOR DATA CENTER” and filed to the China National Intellectual Property Administration on Nov. 1, 2023, the entire contents of which are incorporated herein by reference.

### TECHNICAL FIELD

The present disclosure relates to the field of liquid cooling device technology, and more particularly, to a box-type liquid cooling device for a data center.

### BACKGROUND

At present, in the era of big data explosion, especially with the development of AI technologies, data volume is growing exponentially. Data centers for computation and storage of the data have also shown a development trend of high density and high power. One problem brought about by such development is heat dissipation. Conventional air cooling systems have gradually become overwhelmed, while liquid cooling technology has emerged due to its higher efficiency and lower energy consumption. An application publication number CN206061395U provides a box-type liquid cooling radiator, which includes a lower shell and an upper cover plate. A sealing element is arranged on a top of the lower shell, and a water nozzle fitting is also arranged on a side wall surface of the lower shell, where the water nozzle fitting is communicated with a flow channel. In the present disclosure, a low-temperature liquid flowing through the flow channel is injected to dissipate heat from heating components inside the lower shell. This liquid cooling heat dissipation can quickly and effectively dissipate the heat from the heating components. Furthermore, the flow channel for heat dissipation is arranged on each of five wall surfaces of the box-type liquid cooling radiator, which can comprehensively dissipate the heat from the heating components inside the lower shell, thereby ensuring reliability of power devices. Due to higher heat dissipation of servers in the data centers, the method of dissipating heat through contact between part of the heating components and a coolant provided by existing technologies cannot achieve sufficient heat dissipation effects. Therefore, the existing technologies need to be improved.

### SUMMARY

The present disclosure provides a box-type liquid cooling device for a data center to solve a problem that heat-conducting liquid cooling cannot achieve sufficient heat dissipation effects due to higher temperature of a server in the data center.

The box-type liquid cooling device for the data center provided by embodiments of the present disclosure includes a box body, where a box door is hinged on the box body, and a control box is fixedly installed on the box door. A ventilation mechanism is arranged on the box body, a mounting plate is connected to interior of the box body through a screw, and a support frame is connected to the interior of the box body through the screw. A liquid cooling tank is fixedly connected to the mounting plate, the liquid cooling tank is connected to the support frame through the screw, a heat exchange box is fixedly connected to the support frame, and a pump body is fixedly installed at an upper end of the heat exchange box.

The ventilation mechanism includes a dust cover, a mounting bracket, a motor, and a fan blade. An outer side of the box body is fixedly connected to the dust cover, the interior of the box body is fixedly connected to the mounting bracket, and the motor is fixedly installed inside the mounting bracket, where an output shaft of the motor is fixedly connected to the fan blade. The ventilation mechanism is advantageous to dissipate heat from the interior of the box body.

In the box-type liquid cooling device for the data center of the present disclosure, an upper end of the liquid cooling tank is fixedly connected to a cable pipe, where the cable pipe is fixedly connected to the box body, and the upper end of the liquid cooling tank is fixedly connected to a liquid replenishing pipe. The liquid replenishing pipe is fixedly connected to the box body, and the liquid cooling tank is fixedly connected to a liquid inlet pipe, where one end of the liquid inlet pipe is fixedly connected to the pump body.

In the box-type liquid cooling device for the data center of the present disclosure, a liquid outlet pipe is fixedly connected to the liquid cooling tank, and the liquid outlet pipe is fixedly connected to the heat exchange box, where one end of the liquid outlet pipe is fixedly connected to a heat exchanger. Both the liquid inlet pipe and the liquid outlet pipe are advantageous to cyclic utilization of a coolant inside the liquid cooling tank.

In the box-type liquid cooling device for the data center of the present disclosure, a lower end of the liquid cooling tank is fixedly connected to a liquid drainage pipe, and a liquid drainage valve is arranged on the liquid drainage pipe. The liquid drainage valve can control drainage of the coolant inside the liquid cooling tank.

In the box-type liquid cooling device for the data center of the present disclosure, a heat exchanger is fixedly connected to interior of the heat exchange box, a water inlet pipe is fixedly connected to the heat exchange box, and a water drainage pipe is fixedly connected to a lower end of the heat exchange box. A water drainage valve is arranged on the water drainage pipe, and a connecting pipe is fixedly connected to the heat exchanger, which can accelerate cooling of the coolant.

In the box-type liquid cooling device for the data center of the present disclosure, the connecting pipe is fixedly connected to the heat exchange box, and one end of the connecting pipe is fixedly connected to the pump body, which can achieve cyclic utilization of the coolant.

The technical solutions provided in the embodiments of the present disclosure may include following beneficial effects. The present disclosure designs a box-type liquid cooling device for a data center. Structures such as a liquid replenishing pipe, a liquid inlet pipe, a liquid outlet pipe, and a liquid drainage pipe are additionally arranged on the liquid cooling tank. Sufficient coolant is added into the liquid cooling tank through the liquid replenishing pipe, and a server is completely immersed into the coolant, such that the coolant may come into contact with all heat dissipation components. Through circulation flow between the liquid inlet pipe and the liquid outlet pipe, the coolant can continuously dissipate heat inside the liquid cooling tank, which is more practical.

The present disclosure designs a box-type liquid cooling device for a data center. Structures such as a heat exchange box or heat exchanger are arranged on the support frame. The pump body extracts the coolant from the liquid cooling tank, and the coolant flows into the heat exchanger. After being subjected to water cooling, the coolant flows into the liquid cooling tank through the pump body. When the coolant is outside the liquid cooling tank, it may be cooled to a certain extent, such that the coolant can be reduced to a certain temperature when it flows back to the liquid cooling tank.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a three-dimensional view of an overall structure according to the present disclosure;

FIG. 2 is a three-dimensional view of a local structure in FIG. 1;

FIG. 3 is an enlarged cutaway side elevation view of a ventilation mechanism in FIG. 1; and

FIG. 4 is an enlarged cutaway side elevation view of a heat exchange box in FIG. 1.

Reference numerals in the accompanying drawings: box body 1; box door 2; control box 3; ventilation mechanism 4; mounting plate 5; support frame 6; liquid cooling tank 7; heat exchange box 8; pump body 9; dust cover 41; mounting bracket 42; motor 43; fan blade 44; cable pipe 71; liquid replenishing pipe 72; liquid inlet pipe 73; liquid outlet pipe 74; liquid drainage pipe 75; liquid drainage valve 76; heat exchanger 81; water inlet pipe 82; water drainage pipe 83; water drainage valve 84; and connecting pipe 85.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should also be understood that the terms used in this specification of the present disclosure are only for the purpose of describing particular embodiments and are not intended to limit the present disclosure. As used in the specification and the appended claims of the present disclosure, the singular forms of “a”, “an” and “the” may be intended to include the plural forms, unless the context clearly indicates otherwise.

It should also be further understood that the term “and/or” used in the specification and the appended claims of the present disclosure refers to any combination of one or more of the relevantly listed items and all possible combinations, and includes these combinations.

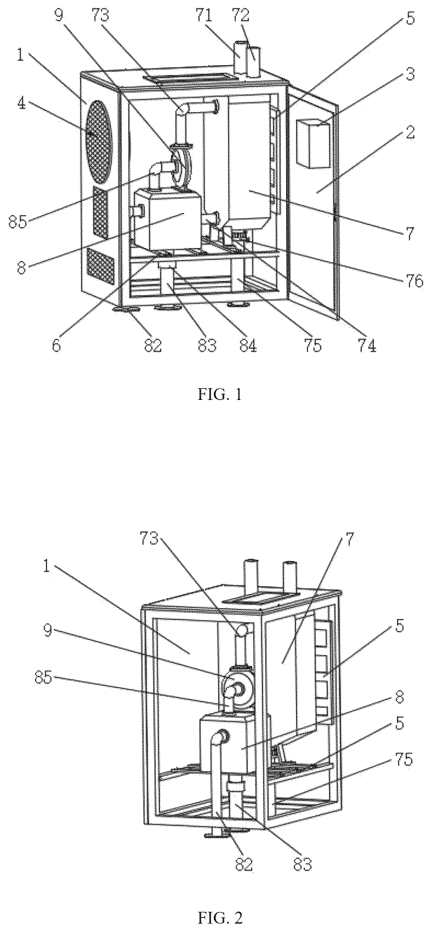

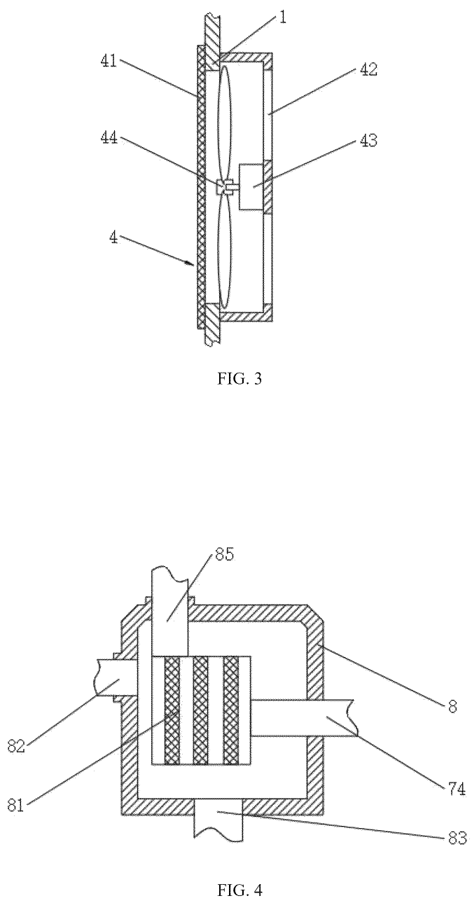

Referring to FIG. 1, FIG. 2, and FIG. 3, the present disclosure discloses a box-type liquid cooling device for a data center, including a box body 1, where a box door 2 is hinged on the box body 1, and a control box 3 is fixedly installed on the box door 2. A ventilation mechanism 4 is arranged on the box body 1, a mounting plate 5 is connected to interior of the box body 1 through a screw, and a support frame 6 is connected to the interior of the box body 1 through the screw. A liquid cooling tank 7 is fixedly connected to the mounting plate 5, the liquid cooling tank 7 is connected to the support frame 6 through the screw, a heat exchange box 8 is fixedly connected to the support frame 6, and a pump body 9 is fixedly installed at an upper end of the heat exchange box 8.

Referring to FIG. 1 and FIG. 2, the ventilation mechanism 4 includes a dust cover 41, a mounting bracket 42, a motor 43, and a fan blade 44. An outer side of the box body 1 is fixedly connected to the dust cover 41, which can block dust in external air outside and reduce attachment of the dust to internal components, thereby preventing adversely affecting internal heat dissipation. The interior of the box body 1 is fixedly connected to the mounting bracket 42, and the motor 43 is fixedly installed inside the mounting bracket 42, where an output shaft of the motor 43 is fixedly connected to the fan blade 44. The ventilation mechanism 4 is advantageous to dissipate heat from the interior of the box body 1.

Referring to FIG. 1 and FIG. 3, an upper end of the liquid cooling tank 7 is fixedly connected to a cable pipe 71, where the cable pipe 71 is fixedly connected to the box body 1, and the upper end of the liquid cooling tank 7 is fixedly connected to a liquid replenishing pipe 72. The liquid replenishing pipe 72 is fixedly connected to the box body 1, and the liquid cooling tank 7 is fixedly connected to a liquid inlet pipe 73, where one end of the liquid inlet pipe 73 is fixedly connected to the pump body 9. A liquid outlet pipe 74 is fixedly connected to the liquid cooling tank 7, and the liquid outlet pipe 74 is fixedly connected to the heat exchange box 8, where one end of the liquid outlet pipe 74 is fixedly connected to a heat exchanger 81. Both the liquid inlet pipe 73 and the liquid outlet pipe 74 are advantageous to cyclic utilization of a coolant inside the liquid cooling tank 7. A lower end of the liquid cooling tank 7 is fixedly connected to a liquid drainage pipe 75, and a liquid drainage valve 76 is arranged on the liquid drainage pipe 75. The liquid drainage valve 76 can control drainage of the coolant inside the liquid cooling tank 7. A heat exchanger 81 is fixedly connected to interior of the heat exchange box 8, a water inlet pipe 82 is fixedly connected to the heat exchange box 8, and a water drainage pipe 83 is fixedly connected to a lower end of the heat exchange box 8. A water drainage valve 84 is arranged on the water drainage pipe 83, and a connecting pipe 85 is fixedly connected to the heat exchanger 81, where the heat exchanger 81 can more effectively conduct heat between the internal coolant and external cold water, thereby accelerating cooling of the coolant, such that the coolant maintains a lower temperature when it returns to the liquid cooling tank 7. The connecting pipe 85 is fixedly connected to the heat exchange box 8, and one end of the connecting pipe 85 is fixedly connected to the pump body 9, where the pump body 9 can extract the coolant through an input end and discharge it from an output end, thereby achieving cyclic utilization of the coolant between the pipeline and the liquid cooling tank 7.

Specific implementation processes of the present disclosure are as follows. During installation, various pipelines and components are connected to each other. A server of the data center is installed inside the liquid cooling tank 7, and the server is connected to outside through the cable pipe 71. When in use, sufficient coolant is first replenished into the liquid cooling tank 7 through the liquid replenishing pipe 72, such that server is completely soaked into the coolant. As a chemical solvent, the coolant is Fluorinert liquid, which is colorless, transparent, odorless, safe and non-toxic. Perfluorinated liquid has an excellent dielectric constant, stable chemical inertness, good thermal conductivity, extremely low surface tension and kinematic viscosity, and system compatibility. Its insulating and noncombustible inertness characteristics being applied in the coolant for the data center, the perfluorinated liquid is the most widely-used submerged coolant so far. The pump body 9 is started again, and the pump body 9 extracts the coolant out of the liquid cooling tank 7 through the connecting pipe 85, the heat exchanger 81, and the liquid outlet pipe 74. Cold water is filled into the heat exchange box 8 through the liquid inlet pipe 82, and then the cold water is discharged through the water drainage pipe 83, allowing the cold water inside the heat exchange box 8 to flow and maintain lower temperature. The high-temperature coolant flows into the heat exchanger 81 through the liquid outlet pipe 74, and the high-temperature coolant quickly carries out heat conduction with the external cold water through the heat exchanger 81, thereby accelerating decrease in temperature of the coolant. After the coolant dissipates heat, it flows back into the connecting pipe 85. After passing through pump body 9, the coolant flows back into the liquid cooling tank 7 from the liquid inlet pipe 73 to dissipate heat from the server. While heat is dissipated internally, the ventilation mechanism 4 on the box body 1 is started synchronously, and the output shaft of the motor 43 rotates, driving the fan blade 44 to rotate, such that an airflow blowing outward is generated to ventilate the interior of the box body 1, which accelerates flow of the air inside the box body 1. When the airflow circulates, it brings the high-temperature air of the device, thereby improving the heat dissipation effects. After a period of use, certain impurities may be carried inside the coolant. In this case, the coolant needs to be replaced. The liquid drainage valve 76 is opened to discharge the coolant with the impurities, and then the liquid drainage valve 76 is closed. Next, the coolant is replenished through the liquid replenishing pipe 72. Thus the coolant can be used again. It is simple in operation and practical in use.

The preceding descriptions are merely specific embodiments of the present disclosure, but the protection scope of the present disclosure is not limited thereto. Any equivalent modifications or replacements easily conceivable to a person of skilled in the art within the technical scope disclosed in the present disclosure shall fall within the protection scope of the present disclosure. Therefore, the protection scope of the present disclosure shall be subject to that of the claims.

What is claimed is:

1. A box-type liquid cooling device for a data center, comprising a box body, wherein a box door is hinged on the box body, a control box is fixedly installed on the box door, a ventilation mechanism is arranged on the box body, a mounting plate is connected to interior of the box body through a screw, a support frame is connected to the interior of the box body through the screw, a liquid cooling tank is fixedly connected to the mounting plate, the liquid cooling tank is connected to the support frame through the screw, a heat exchange box is fixedly connected to the support frame, and a pump body is fixedly installed at an upper end of the heat exchange box; and
the ventilation mechanism comprises a dust cover, a mounting bracket, a motor, and a fan blade; an outer side of the box body is fixedly connected to the dust cover, the interior of the box body is fixedly connected to the mounting bracket, the motor is fixedly installed inside the mounting bracket, and an output shaft of the motor is fixedly connected to the fan blade.

2. The box-type liquid cooling device for the data center according to claim 1, wherein an upper end of the liquid cooling tank is fixedly connected to a cable pipe, the cable pipe is fixedly connected to the box body, the upper end of the liquid cooling tank is fixedly connected to a liquid replenishing pipe, the liquid replenishing pipe is fixedly connected to the box body, the liquid cooling tank is fixedly connected to a liquid inlet pipe, and one end of the liquid inlet pipe is fixedly connected to the pump body.

3. The box-type liquid cooling device for the data center according to claim 1, wherein a liquid outlet pipe is fixedly connected to the liquid cooling tank, the liquid outlet pipe is fixedly connected to the heat exchange box, and one end of the liquid outlet pipe is fixedly connected to a heat exchanger.

4. The box-type liquid cooling device for the data center according to claim 1, wherein a lower end of the liquid cooling tank is fixedly connected to a liquid drainage pipe, and a liquid drainage valve is arranged on the liquid drainage pipe.

5. The box-type liquid cooling device for the data center according to claim 1, wherein a heat exchanger is fixedly connected to interior of the heat exchange box, a water inlet pipe is fixedly connected to the heat exchange box, a water drainage pipe is fixedly connected to a lower end of the heat exchange box, a water drainage valve is arranged on the water drainage pipe, and a connecting pipe is fixedly connected to the heat exchanger.

6. The box-type liquid cooling device for the data center according to claim 5, wherein the connecting pipe is fixedly connected to the heat exchange box, and one end of the connecting pipe is fixedly connected to the pump body.
